(19) United States
(12) Patent Application Publication
(10) Pub. No.: US 2025/0142929 A1
(43) Pub. Date: May 1, 2025

(54) SEMICONDUCTOR DEVICES

(71) Applicant: Samsung Electronics Co., Ltd., Suwon-si (KR)

(72) Inventors: Kyungbin CHUN, Suwon-si (KR); Gyeom KIM, Suwon-si (KR); Ryong HA, Suwon-si (KR)

(73) Assignee: Samsung Electronics Co., Ltd., Suwon-si (KR)

(21) Appl. No.: 18/666,120

(22) Filed: May 16, 2024

(30) Foreign Application Priority Data
Oct. 25, 2023 (KR) 10-2023-0143820

(51) Int. Cl. H01L 29/417; H01L 29/10; H01L 29/167; H01L 29/66

(52) U.S. Cl. CPC H10D 64/256; H10D 62/235; H10D 62/834; H10D 64/018

(57) ABSTRACT

A semiconductor device includes a substrate; an active pattern on the substrate; a plurality of channel layers stacked on the active pattern to be spaced apart from each other; a gate structure surrounding the plurality of channel layers; source/drain patterns including a first epitaxial layer disposed along side surfaces of the plurality of channel layers on a portion of the active pattern and a second epitaxial layer disposed on the first epitaxial layer and having a trench; contact structures disposed on the source/drain patterns, respectively, and including a first extension portion filling the trench, and a pair of second extension portions extending along both side surfaces of the source/drain patterns in the second direction, respectively; and a metal-semiconductor compound layer disposed between the source/drain patterns and the contact structures.

### CROSS-REFERENCE TO RELATED APPLICATION(S)

This application claims benefit of priority to Korean Patent Application No. 10-2023-0143820 filed on Oct. 25, 2023 in the Korean Intellectual Property Office, the disclosure of which is incorporated herein by reference in its entirety.

### BACKGROUND

Example embodiments of inventive concepts relate to a semiconductor device.

As demand for high performance, high speed, and/or multifunctionality of a semiconductor device has increased, demand for higher integration density of a semiconductor device has also increased. To meet the demand for higher integration density of a semiconductor device, the development of a semiconductor device including three-dimensional channels has been actively conducted.

### SUMMARY

Various example embodiments of inventive concepts provide a semiconductor device having improved electrical properties.

Some example embodiments of inventive concepts provide a semiconductor device including a substrate; an active pattern extending on the substrate in a first direction; a device isolation layer on the substrate and defining the active pattern; a plurality of channel layers arranged on the active pattern and spaced apart from each other in a direction perpendicular to an upper surface of the substrate; a gate structure crossing the active pattern, surrounding the plurality of channel layers, and the gate structure extending in a second direction intersecting the first direction; source/drain patterns including a first epitaxial layer on a portion of the active pattern at both sides of the gate structure along side surfaces of the plurality of channel layers and a second epitaxial layer on the first epitaxial layer and having a trench; contact structures on the source/drain patterns, respectively, and including a first extension portion filling the trench, and a pair of second extension portions extending along both side surfaces of each of the source/drain patterns in the second direction, respectively; and a metal-semiconductor compound layer between the source/drain patterns and the contact structures.

Some example embodiments of inventive concepts provide a semiconductor device including a substrate; an active pattern extending on the substrate in a first direction; a plurality of channel layers arranged on the active pattern and spaced apart from each other in a direction perpendicular to an upper surface of the substrate; a gate structure crossing the active pattern, and surrounding the plurality of channel layers, and the gate structure extending in a second direction intersecting the first direction; fence spacers on both side surfaces of the active pattern in the second direction at both sides of the gate structure; source/drain patterns including epitaxial layers connected to side surfaces of the plurality of channel layers, respectively, on a portion of the active pattern on both sides of the gate structure, and the source/drain patterns having a trench in the epitaxial layer; and contact structures on the source/drain patterns, respectively, each contact structure including a first extension portion filling the trench, and a pair of second extension portions extending to the fence spacers, respectively, along both side surfaces of each of the source/drain patterns in the second direction.

Some example embodiments of inventive concepts provide a semiconductor device including a substrate; an active pattern extending on the substrate in a first direction; a plurality of channel layers arranged on the active pattern and spaced apart from each other in a direction perpendicular to an upper surface of the substrate; a gate structure crossing the active pattern, surrounding the plurality of channel layers, and extending in a second direction intersecting the first direction; source/drain patterns including a first epitaxial layer along side surfaces of the plurality of channel layers on a portion of the active pattern, and a second epitaxial layer on the first epitaxial layer and having a trench deeper than a level of an upper surface of a lowermost channel layer among the plurality of channel layers; contact structures on the source/drain patterns, respectively, each contact structure including a first extension portion filling the trench and a pair of second extension portions extending along both side surfaces of each of the source/drain patterns in the second direction; and a metal-semiconductor compound layer between the source/drain patterns and the contact structures.

### BRIEF DESCRIPTION OF DRAWINGS

The above and other aspects, features, and advantages in the example embodiments will be more clearly understood from the following detailed description, taken in combination with the accompanying drawings, in which:

FIG. 1 is a plan diagram illustrating a semiconductor device according to an example embodiment;

FIG. 2 is a cross-sectional diagram illustrating a semiconductor device taken along line I-I′ in FIG. 1 according to an example embodiment, viewed from the side;

FIGS. 3A and 3B are cross-sectional diagrams illustrating a semiconductor device taken along lines II1-II1′ and II2-II2′ in FIG. 1 according to an example embodiment, viewed from the side;

FIGS. 4A and 4B are plan diagrams illustrating portion “A” in FIG. 1 cut-out on a PL (e.g., see FIG. 2) level;

FIGS. 5A and 5B are cross-sectional diagrams illustrating a semiconductor device according to an example embodiment, viewed from the side;

FIG. 6 is a cross-sectional diagram illustrating a semiconductor device according to an example embodiment, viewed from the side;

FIGS. 7A to 7D are cross-sectional diagrams illustrating a portion of processes (e.g., forming a fin structure and a dummy gate structure) of a method of manufacturing a semiconductor device according to an example embodiment;

FIGS. 8A to 8F are cross-sectional diagrams illustrating another portion of processes (e.g., forming a source/drain pattern) of a method of manufacturing a semiconductor device according to an example embodiment; and

FIGS. 9A to 9D are cross-sectional diagrams illustrating the other portion of processes (e.g., forming a contact structure) of a method of manufacturing a semiconductor device according to an example embodiment.

### DETAILED DESCRIPTION

Hereinafter, various example embodiments will be described as follows with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

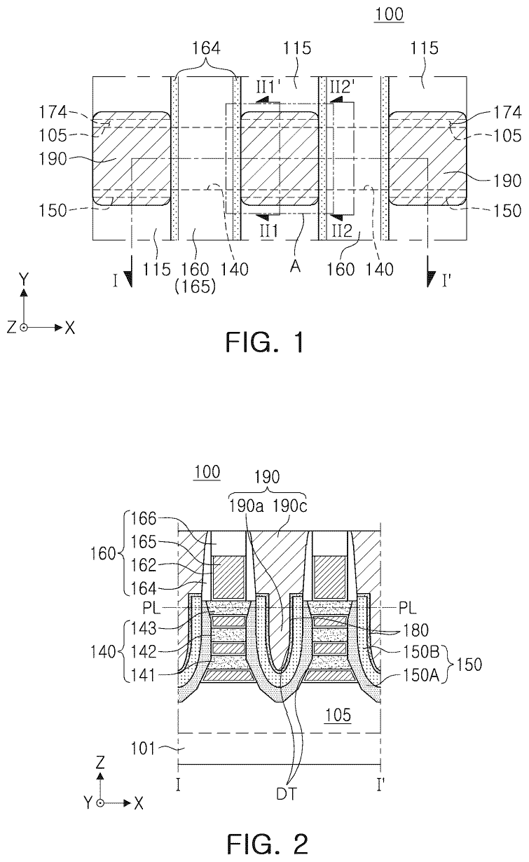

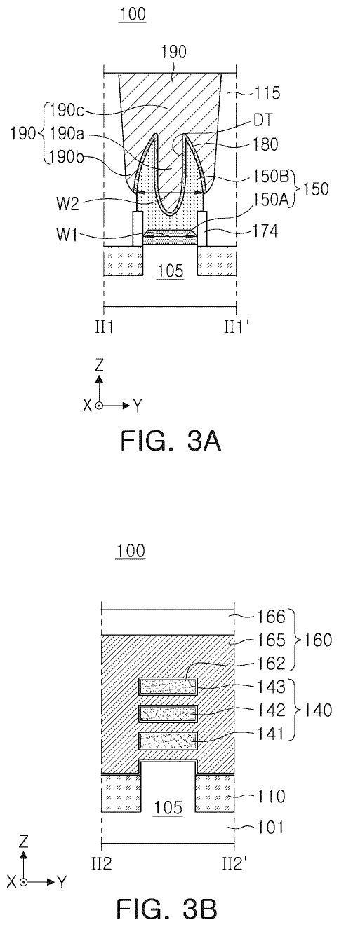

FIG. 1 is a plan diagram illustrating a semiconductor device according to an example embodiment. FIG. 2 is a cross-sectional diagram illustrating a semiconductor device taken along line I-I′ in FIG. 1 according to an example embodiment. FIGS. 3A and 3B are cross-sectional diagrams illustrating a semiconductor device taken along lines II1-II1′ and II2-II2′ in FIG. 1 according to an example embodiment, viewed from the side.

Referring to FIGS. 1, 2, 3A and 3B, a semiconductor device 100 according to the example embodiment may include a substrate 101, an active pattern 105 protruding on the substrate 101 and extending in the first direction (e.g., X-direction), a plurality of channel layers 141, 142, and 143 disposed on the active pattern 105, and a gate structure 160 crossing the active pattern 105 and extending in the second direction (e.g., Y-direction). The plurality of channel layers 141, 142, and 143 may be spaced apart from the active pattern 105 in a direction perpendicular to an upper surface of the substrate 101 (e.g., Z-direction).

The semiconductor device 100 may further include source/drain patterns 150 disposed on both sides of the gate structure 160 and in contact with both side surfaces of the plurality of channel layers 141, 142, and 143, a metal-semiconductor compound layer 180 disposed on the source/drain patterns 150, and contact plugs 190 connected to the source/drain patterns 150 through the metal-semiconductor compound layer 180. The semiconductor device according to some example embodiments may be a P-type MOSFET.

In some example embodiments, the active pattern 105 may extend in the first direction (e.g., X-direction) and may have a protruding fin-type structure as described above. For example, the substrate 101 may be a semiconductor substrate such as a silicon substrate or germanium substrate, or a silicon-on-insulator (SOI) substrate.

Referring to FIGS. 3A and 3B, the device isolation layer 110 may define the active pattern 105. The device isolation layer 110 may be disposed on the substrate 101 to cover a side surface of the active pattern 105 of the substrate 101. The device isolation layer 110 may be formed such that the upper region of active pattern 105 may be exposed. In some example embodiments, the device isolation layer 110 may have a curved upper surface having a higher level toward the active pattern 105. For example, the device isolation layer 110 may include an oxide film, a nitride film, or a combination thereof.

In some example embodiments, the device isolation layer 110 may be formed by a shallow trench isolation (STI) process. In some example embodiments, the device isolation layer 110 may further include a region extending deeper below an upper surface of the substrate 101. The regions extending deeper may also be referred to as deep trench isolation (DTI).

Referring to FIGS. 2 and 3B along with FIG. 1, an upper surface of the active pattern 105 may protrude from an upper surface of the device isolation layer 110 as described above. The channel structure 130 employed in the example embodiment may include three channel layers 141, 142, and 143 spaced apart from the upper surface of the active pattern 105 in a direction perpendicular to the upper surface of the substrate 101 (e.g., Z-direction), but example embodiments thereof are not limited thereto, and the number of the channel layers included in the channel structure 130 may be different from the above-mentioned example (e.g., four channel layers).

As illustrated in FIG. 2, the gate structure 160 may include a gate electrode 165 extending in the second direction (e.g., Y-direction) and surrounding the plurality of channel layers 141, 142, and 143, a gate insulating layer 162 disposed between the gate electrode 165 and the plurality of channel layers 141, 142, and 143, gate spacers 164 disposed on side surfaces of the gate electrode 162, and a gate capping layer 166 disposed on the gate electrode 165.

The gate insulating layer 162 may be disposed between the active pattern 105 and the gate electrode 165 and between the plurality of channel layers 141, 142, and 143 and the gate electrode 165 as illustrated in FIG. 2. The gate insulating layer 162 may be formed to surround the plurality of channel layers 141, 142, 143 in the second direction (e.g., Y-direction), and may extend from an upper surface of the active pattern 105 to an upper surface of the device isolation layer 110 (e.g., see FIG. 3B). For example, the gate insulating layer 162 may include oxide, nitride, or a high-κ material. The high-κ material may refer to a dielectric material having a higher dielectric constant than that of silicon oxide (SiO₂). The high-κ material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃), but example embodiments are not limited thereto.

The gate electrode 165 may fill a space between the plurality of channel layers 141, 142, and 143 above the active pattern 105 and may extend to an upper portion of the fourth channel layer 134, which is an uppermost layer. The gate electrode 165 may be spaced apart from the plurality of channel layers 141, 142, and 143 by the gate insulating layer 162. The gate electrode 165 may include a conductive material, for example, a metal nitride such as titanium nitride film (TiN), tantalum nitride film (TaN), or tungsten nitride film (WN), and/or a metal material such as aluminum (Al), tungsten (W), or molybdenum (Mo) or a semiconductor material such as doped polysilicon, but example embodiments are not limited thereto. In some example embodiments, the gate electrode 165 may include two or more multilayers.

The gate spacers 164 may be disposed on both side surfaces of the gate electrode 165. The gate spacers 164 may insulate the source/drain patterns 150 and the gate electrodes 165. In some example embodiments, the gate spacers 164 may include a multilayer structure. For example, the gate spacers 164 may include oxide, nitride and oxynitride, and especially a low-κ film.

Referring to FIGS. 1 and 2, a recess for the source/drain patterns 150 may be formed by partially removing the channel structure 130 and the active pattern 105 disposed on both sides of the gate structure 160. Side surfaces of the plurality of channel layers 141, 142, and 143 may be exposed through the recess, and the source/drain patterns 150 may be in contact with both side surfaces of each of the plurality of channel layers 141, 142, and 143 in the first direction (e.g., X-direction).

Referring to FIG. 2, widths of the first to third channel layers 141, 142, 143 in the first direction (e.g., X-direction) may be the same as or similar (e.g., relatively smaller (or smaller)) to a width of the active pattern 105. Also, widths of the first to third channel layers 141, 142, 143 in the first direction (e.g., X-direction) may be the same as or similar to a width of the gate structure 160. In some example embodiments, the widths of the first to third channel layers 141, 142, and 143 may be slightly different (or may be different) from each other.

The first to third channel layers 141, 142, and 143 may include a semiconductor material which may provide a channel region. For example, the first to third channel layers 141, 142, and 143 may be a semiconductor pattern such as silicon (Si), silicon germanium (SiGe), or germanium (Ge). In some example embodiments, the first to third channel layers 141, 142, and 143 may be formed of the same material (e.g., silicon) as that of the substrate 101. In some example embodiments, a region adjacent to the source/drain pattern 150 of the first to third channel layers 141, 142, and 143 may include an impurity region.

The semiconductor device according to the example embodiment may be a P-type MOSFET, and each of the source/drain patterns 150 may include an epitaxial layer doped with P-type impurities. For example, P-type impurities may include at least one of B, Al, Ga, and In. In some example embodiments, the source/drain patterns 150 may include a first epitaxial layer 150A disposed along side surfaces of the plurality of channel layers 141, 142, and 143 on a portion of a region of the active pattern 105 on both sides of the gate structure 160, and a second epitaxial layer 150B disposed on the first epitaxial layer 150A and having a trench DT, as illustrated in FIG. 2. Each of the first and second epitaxial layers 150A and 150B may include silicon germanium (SiGe), and a first concentration of germanium (Ge) in the first epitaxial layer 150A may be higher than a second concentration of germanium (Ge) in the second epitaxial layer 150B. For example, the first concentration of the first epitaxial layer 150A may be 5 atomic % to 20 atomic %, and the second concentration of the second epitaxial layer 150B may be 30 atomic % to 70 atomic %.

In some example embodiments, the first and second epitaxial layers 150A and 150B may include the same or different P-type impurities. Also, the first and second epitaxial layers 150A and 150B may have different impurity concentrations. For example, P-type impurities may include boron (B), and a boron concentration of the second epitaxial layer 150B may be higher than a boron concentration of the first epitaxial layer 150A.

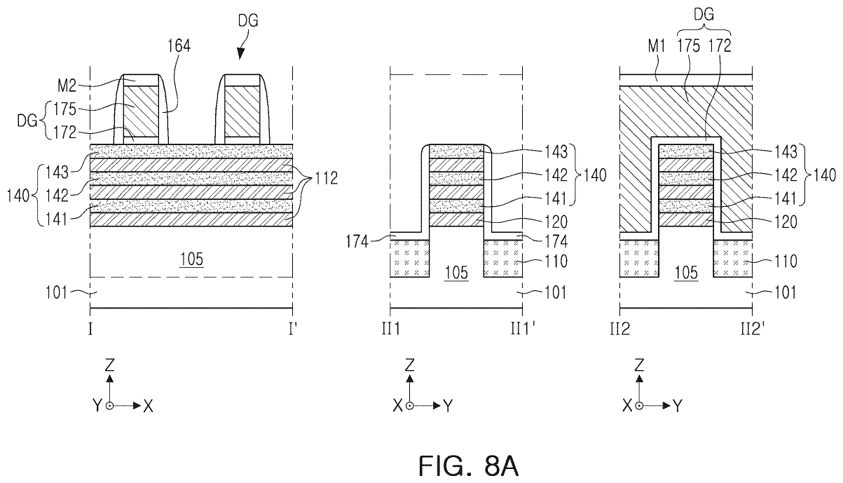

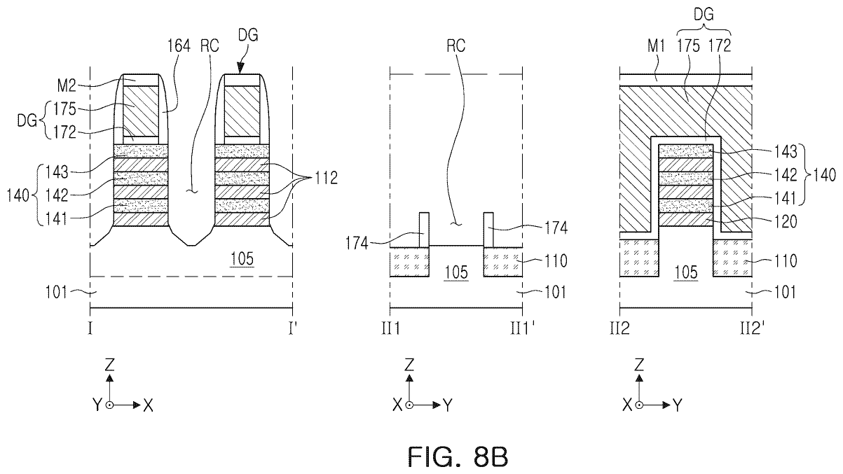

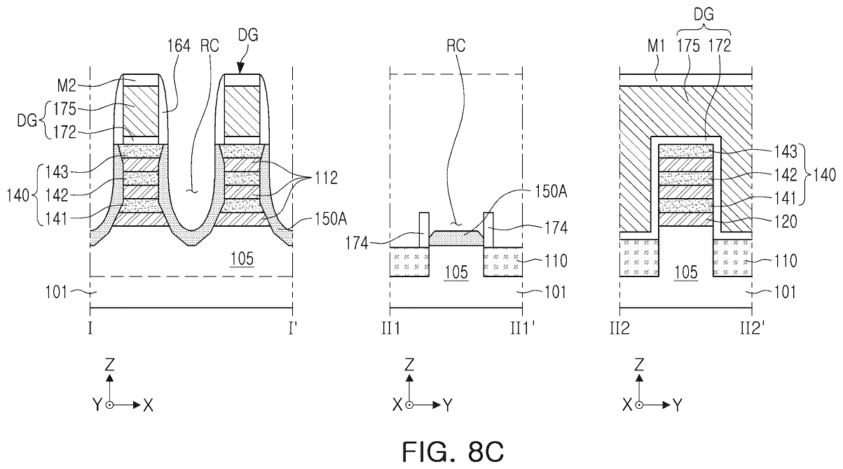

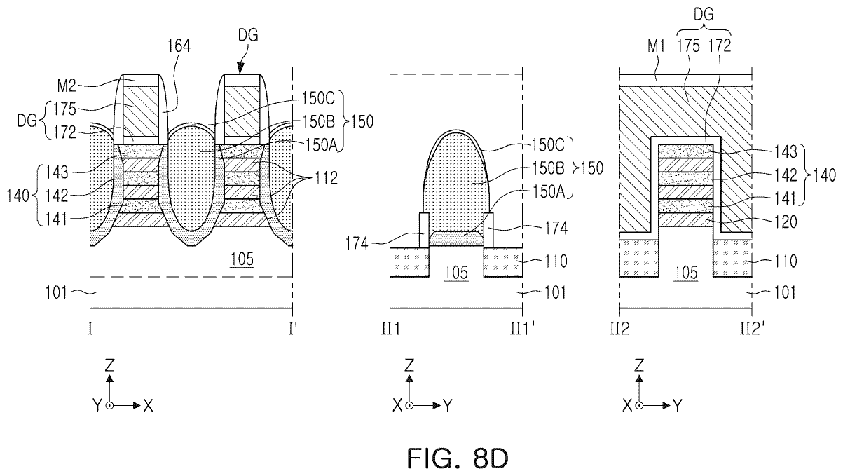

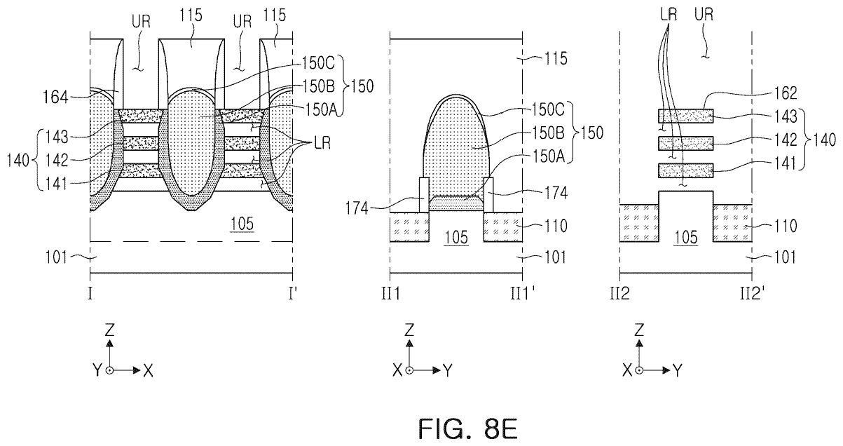

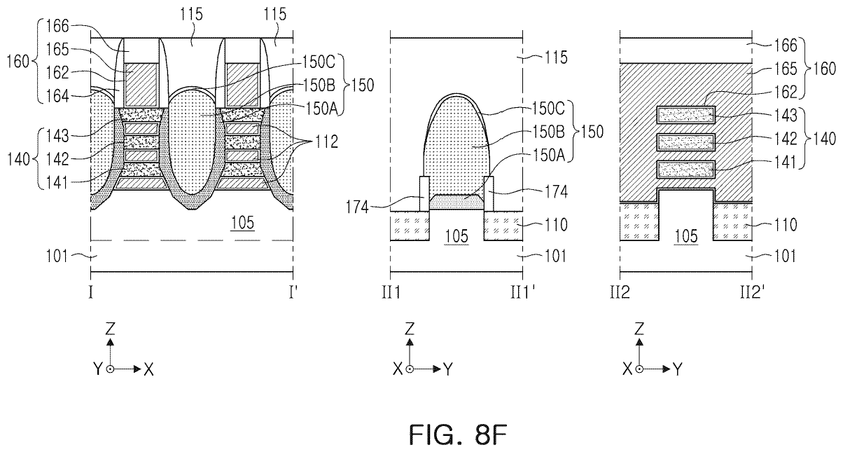

In some example embodiments, the source/drain patterns 150 may include a third epitaxial layer (e.g., see 150C in FIG. 8D) on the second epitaxial layer 150B as a cap layer, but as in some example embodiments, the third epitaxial layer may be metallized with the metal-semiconductor compound layer 180, and may barely remain in a final structure.

The second epitaxial layer 150B employed in some example embodiments may include a trench DT having a sufficient depth (or having a depth). The trench DT may have a bottom level overlapping at least a portion of the first channel layer 141, which is a lowermost layer, in a direction parallel to an upper surface of the substrate 101 (e.g., see FIG. 2).

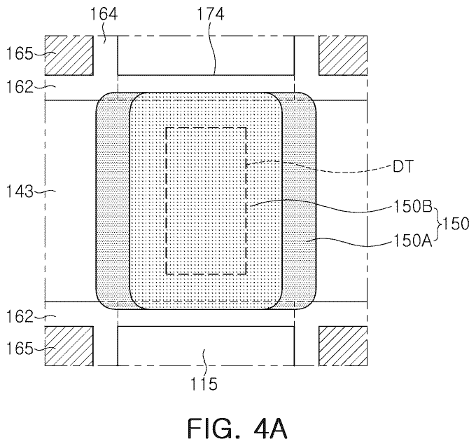

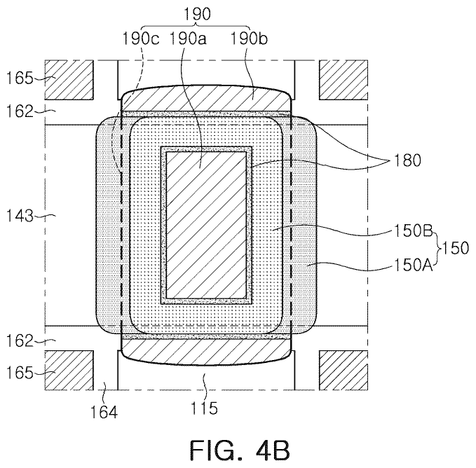

In FIGS. 4A and 4B, a planar shape of the source/drain pattern 150 employed in some example embodiments is illustrated.

FIG. 4B is an enlarged diagram illustrating portion “A” in FIG. 1 on a PL (e.g., see FIG. 2) level, and FIG. 4A is a plan diagram illustrating the example in FIG. 4B in which the contact structure is not provided to understand a planar shape of the source/drain pattern 150.

Referring to FIGS. 2, 3A, and 4B, a trench DT of the source/drain pattern 150 may have a structure surrounded by the second epitaxial layer 150B. Side surfaces of the source/drain pattern 150 in the first direction (e.g., X-direction) may be provided by the first epitaxial layer 150A and may be connected to the channel layers 141, 142, and 143, and a side surface of the source/drain pattern 150 in the second direction (e.g., Y-direction) may be provided by the second epitaxial layer 150B.

The source/drain patterns 150 employed in some example embodiments may have a structure in which growth is suppressed in the second direction (e.g., Y-direction).

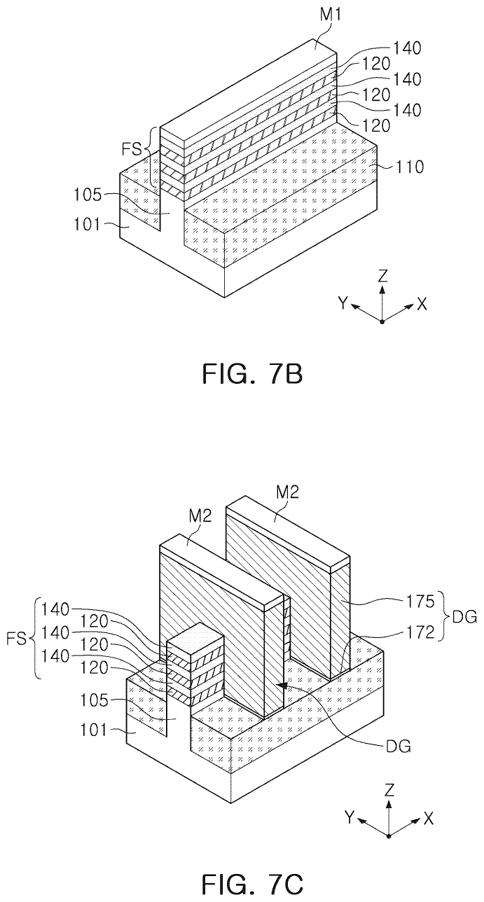

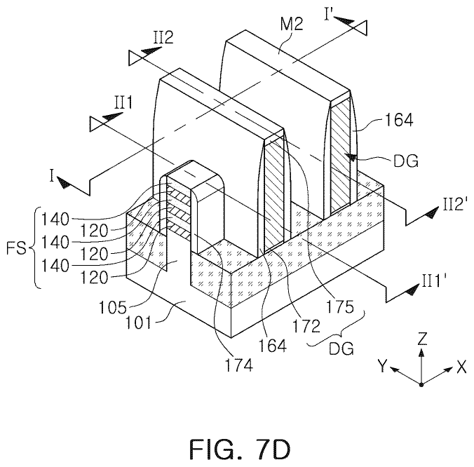

Referring to FIGS. 3A, 4A and 4B, a semiconductor device 100 may further include fence spacers 174 disposed in the second direction (e.g., Y-direction) of the active pattern 105 on both side surfaces of the gate structure 160. The fence spacers 174 may be partially connected to the gate spacers 164. The fence spacers 174 may be formed from a material film formed through the same deposition process as the gate spacers 164 (e.g., see FIG. 7D). The fence spacers 174 may include the same material as that of the gate spacers 164.

Referring to FIG. 3A, a width W1 of a lower region of the source/drain pattern 150 in the second direction (e.g., Y-direction) may be defined by a spacing between the fence spacers 174. A width W2 of an upper region of the source/drain pattern 150 may grow in a lateral direction and may be larger than the spacing between the fence spacers 174, but in some example embodiments, the width W2 of an upper region of the source/drain pattern 150 may be adjusted by suppressing growth in the lateral direction. In some example embodiments, the suppression of growth in this lateral direction may be implemented by adjusting growth conditions of the second epitaxial layer 150B or performing an etching process during the growth process. In some example embodiments, by selecting a crystal growth plan (e.g., a crystal plane of an upper surface of the substrate) as a specific crystal plane, an upper region of the source/drain pattern 150 may be grown less in the lateral direction and may have the width W2 which is relatively narrow (or is narrow).

In some example embodiments, the width (e.g., a maximum width) of the upper region of the source/drain patterns 150 (e.g., the second epitaxial layer) may be greater than the width of the lower region, and may not be greater than the spacing between the side surfaces on the periphery of the fence spacers.

In some example embodiments, the maximum width W2 in the second direction (e.g., Y-direction) of the source/drain patterns 150 (e.g., the second epitaxial layer 150B) may be less than 120% of the width W1 of the lower region disposed between the fence spacers 174. For example, a difference between the maximum width W2 of the source/drain patterns 150 in the second direction (e.g., X-direction) and the width W1 of the portion disposed between the fence spacers 174 may be 20 nm or less.

In some example embodiments, both side surfaces of the upper region of the source/drain patterns 150 (e.g., the second epitaxial layer 150B), may not have a curved portion. In some example embodiments, the source/drain patterns 150 may have almost vertical (or vertical) side surfaces. Also, as illustrated in FIG. 3A, the upper region of the source/drain patterns 150 may have a rounded protrusion. The protrusion may be understood as a structure etched by etching performed simultaneously during the growth process of the second epitaxial layer 150B.

The shape of the source/drain patterns 150 described above may prevent (or reduce) contact with other source/drain patterns 150 adjacent in the second direction (e.g., Y-direction) and may allow the contact structure 190 employed in the example embodiment to be easily formed (or to be formed).

The interlayer insulating layer 115 may be disposed on the device isolation layer 110 and may cover the source/drain patterns 150 and the gate structure 160 (e.g., see FIG. 3A). For example, the interlayer insulating layer 115 may include at least one of oxide, nitride, and oxynitride, and may include a low-κ material.

Referring to FIG. 1, FIGS. 2 and 3A, the semiconductor device 100 according to some example embodiments may include a contact structure 190 penetrating an interlayer insulating layer 115, and a metal-semiconductor compound layer 180 between the source/drain patterns 150 and the contact structure 190. An electrical signal may be applied to the source/drain patterns 150 through the contact structure 190, and contact resistance may be improved through the metal-semiconductor compound layer 180.

Referring to FIGS. 3A and 4B, the contact structure 190 employed in some example embodiments may have a first extension portion 190a filling the trench DT and a pair of second extension portions 190b each extending along both side surfaces of the source/drain pattern 150 in the second direction (e.g., Y-direction).

The first extension portion 190a may overlap at least a portion of the first channel layer 141, which is a lowermost layer, in the horizontal direction. The second extension portions 190b may extend along both side surfaces of the source/drain patterns 150 in the second direction (e.g., Y-direction), for example, along a surface of the second epitaxial layer 150B. The contact structure 190 may greatly improve (or may improve) contact resistance by increasing a contact area with the source/drain patterns 150 through the first extension portion 190a and also the second extension portions 190b.

The metal-semiconductor compound layer 180 may be formed on the upper surface of the contact structure 190 and an internal surface of the trench DT, and also on side surfaces of the source/drain patterns 150 in contact with the second extension portions 190b. The metal-semiconductor compound layer 180 may be formed by metalizing a portion of the source/drain patterns 150. In some example embodiments, when the source/drain patterns 150 include a third epitaxial layer (e.g., 150C in FIG. 8D) on the second epitaxial layer 150B, the third epitaxial layer may be almost entirely metallized (or may be metallized) with a metal-semiconductor compound layer 180. For example, the metal-semiconductor compound layer 180 may include TiGe or TiSiGe.

In some example embodiments, the contact structure 190 may have a structure in which a width of a lower portion may decrease further than a width of an upper portion. A width of the portion of the contact structures 190 adjacent to the gate structure 160 in the second direction (e.g., Y-direction) may be greater than a width of the first extension portion 190a. For example, the contact structure 190 may include a metal material such as aluminum (Al), tungsten (W), or molybdenum (Mo), but example embodiments are not limited thereto. The contact structure 190 may further include a barrier material film such as titanium nitride film (TiN), tantalum nitride film (TaN), or tungsten nitride film (WN) surrounding the metal material, but example embodiments are not limited thereto.

According to some example embodiments, by forming the source/drain pattern 150 to have a small width, and forming the contact structure 190 having a first extension portion 190a extending to the trench DT in the source/drain pattern 150 and a second extension portion 190b extending to both side surfaces of the source/drain pattern 150, contact resistance between the source/drain pattern 150 and the contact structure 190 may be greatly reduced (or may be reduced).

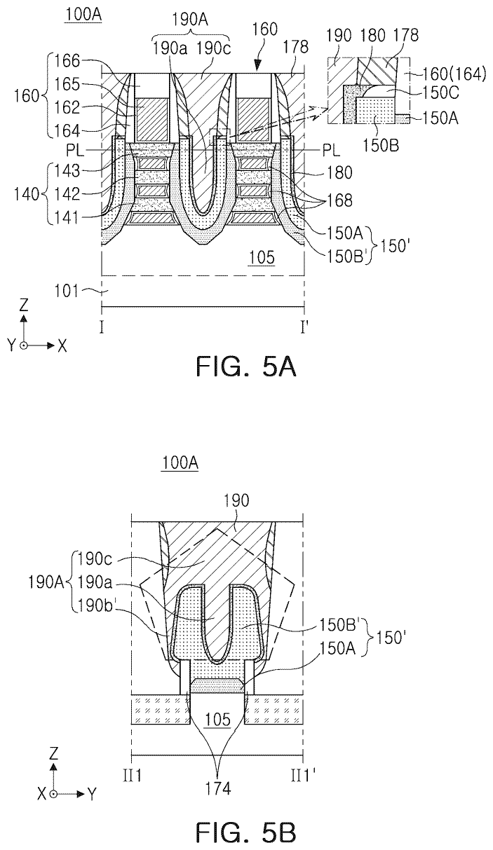

FIGS. 5A and 5B are cross-sectional diagrams illustrating a semiconductor device according to some example embodiments.

Referring to FIGS. 5A and 5B, a semiconductor device 100A according to some example embodiments may be configured the same as or similar to the semiconductor device 100 illustrated in FIGS. 1 to 4B other than the configuration in which the source/drain pattern 150′ has a shape different from a shape of the source/drain pattern 150 in some aforementioned example embodiments, the configuration in which the second extension portions 190b′ of the contact structure 190a extend to the fence spacer 174, the configuration in which the blocking insulating layer 178 on a sidewall of the gate structure 160 and the third epitaxial layer 190C below the insulating blocking layer 178 remain, and the configuration in which the internal spacers 168 are disposed between the plurality of channel layers 141, 142, and 143. Also, unless otherwise indicated, the components of some example embodiment may be understood with reference to the descriptions of the same or similar components of the semiconductor device 100 illustrated in FIGS. 1 to 4B.

The source/drain pattern 150′ employed in some example embodiments may be P-type epitaxial (SiGe). A general P-type source/drain pattern may grow in a lateral direction on fence spacers 174 as indicated by the dotted line, and may have a cross-sectional surface having a pentagonal shape. In some example embodiments, the source/drain pattern 150′ illustrated in FIG. 5B may be grown by controlling growth conditions (e.g., temperature and pressure) of the second epitaxial layer 150B or performing an etching process during the growth process so as to suppress the growth in the lateral direction. The source/drain pattern 150′ may have a trapezoid having a width decreasing upwardly, differently from the shape of the source/drain pattern 150 in some aforementioned example embodiments. A maximum width of source/drain pattern 150′ may be larger than the maximum width in some aforementioned example embodiments, and may be less than 120% of the width of the lower region. Also, an upper end edge of the source/drain pattern 150′ may have a rounded portion.

Also, the contact structure 190a employed in some example embodiments may have a first extension portion 190a disposed in the trench and second extension portions 190b′, similarly to the aforementioned example embodiments. In some example embodiments, the second extension portions 190b′ may pass by both side surfaces of source/drain pattern 150′ and may extend to fence spacers 174. Also, a metal-semiconductor compound layer 180 may be disposed on both side surfaces of the source/drain pattern 150′ on which the second extension portion 190b′ is formed.

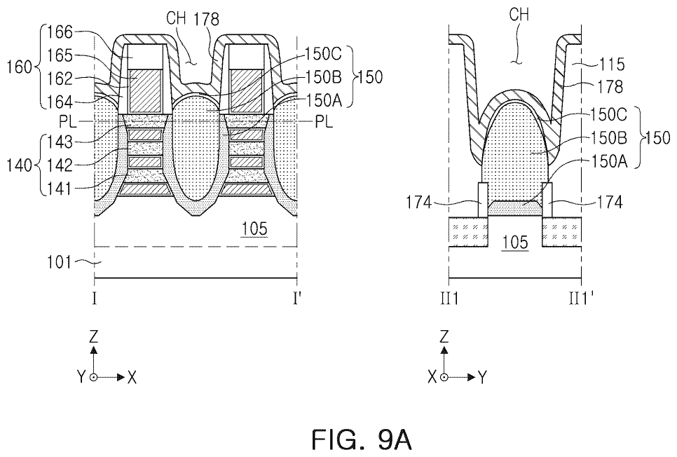

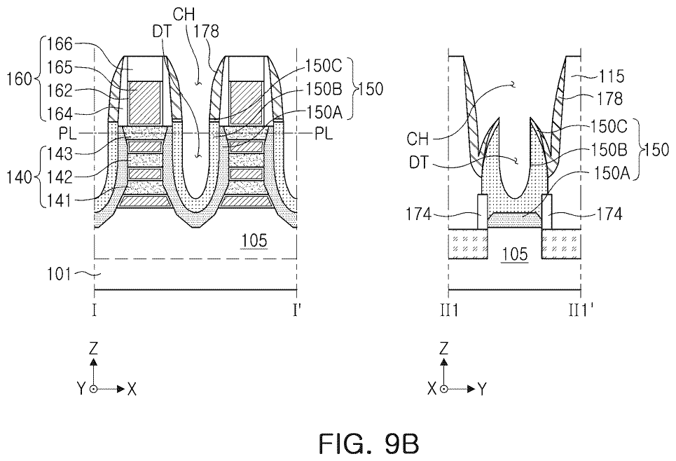

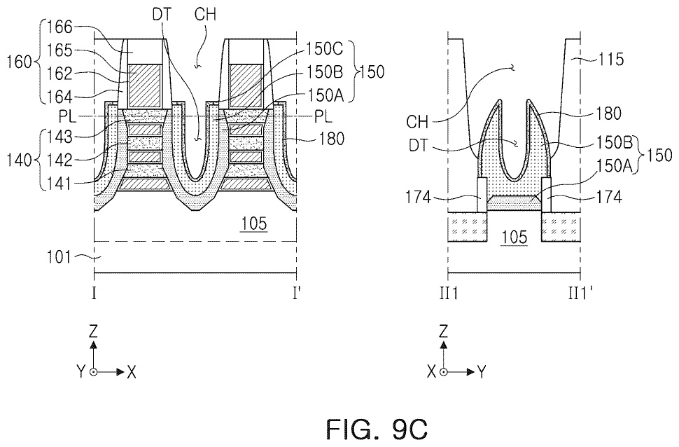

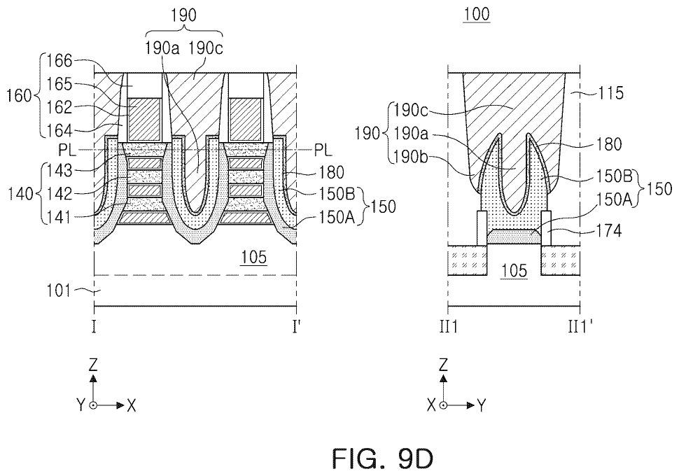

In some example embodiments, the blocking insulating layer 178 may remain on a sidewall of the gate structure 160. The insulating blocking layer 178 may be used to form a contact hole for the contact structure 190 (e.g., see FIG. 9B). In some aforementioned example embodiments, the insulating blocking layer 178 may be removed before the metal-semiconductor compound layer 180 is formed, whereas in some example embodiments, the insulating blocking layer 180 may remain in a portion of a side surface of the contact structure 190, for example, in a sidewall of the gate structure 170 and a portion of the side surface of the interlayer insulating layer 115. Also, in the process of forming the metal-semiconductor compound layer 180, an unmetalized epitaxial portion may remain below the insulating blocking layer 178. In some example embodiments, the epitaxial portion covered by the insulating blocking layer 178 may be a portion of the third epitaxial layer 150C used as a cap layer of the source/drain pattern 150.

In some example embodiments, the semiconductor device 100 may further include internal spacers 168 disposed on both side surfaces of the gate electrode 165 between channel layers 141, 142, and 143 as illustrated in FIG. 2. The gate electrode 165 may be spaced apart from the source/drain regions 150 by the internal spacers 168 and may be electrically separated from each other below the third channel layer 143. The internal spacers 168 may have a side surface in contact with the gate electrode 165 curved toward the gate electrode 165, but some example embodiments thereof are not limited thereto. For example, the internal spacers 168 may include oxides, nitrides and oxynitrides. For example, the internal spacers 168 may be formed of a low-κ film.

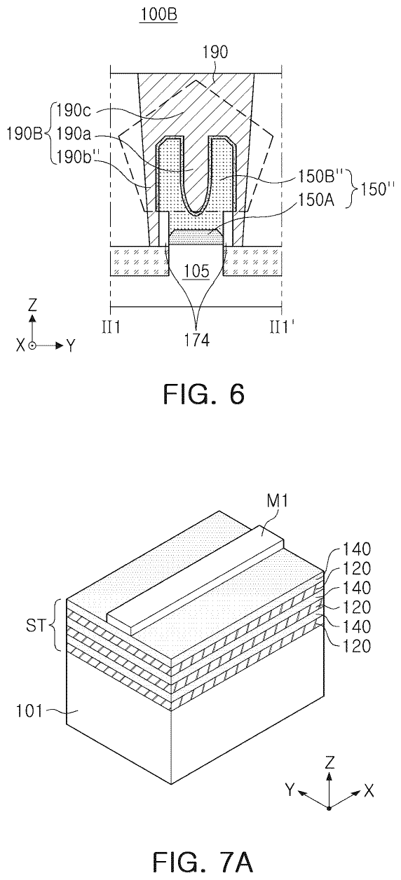

FIG. 6 is a cross-sectional diagram illustrating a semiconductor device according to some example embodiments, viewed from the side.

Referring to FIG. 6, a semiconductor device 100B according to some example embodiments may be configured the same as or similar to the semiconductor device 100 illustrated in FIGS. 1 to 4B other than the configuration in which the source/drain pattern 150″ has a shape different from the shape of the source/drain pattern 150 in aforementioned example embodiments, and the second extension portions 190b′ of the contact structure 190b extend to the device isolation layer 110. Also, unless otherwise indicated, the components of some example embodiments may be understood with reference to the descriptions of the same or similar components of the semiconductor device 100 illustrated in FIGS. 1 to 4B.

The source/drain pattern 150″ employed in some example embodiments may be P-type epitaxial (SiGe). The source/drain pattern 150″ illustrated in FIG. 6 may be grown by controlling the growth conditions (e.g., temperature and pressure) of the second epitaxial layer 150B or performing an etching process during the growth process to suppress growth in the lateral direction. The source/drain pattern 150″ may have an almost rectangular (or rectangular) shape differently from the shape of source/drain pattern 150 in some aforementioned example embodiments. For example, a sidewall of the source/drain pattern 150 may be an almost vertical (or vertical) surface. A maximum width of the source/drain pattern 150 may be larger than a maximum width in some aforementioned example embodiments, and may be less than 120% of a width of a lower region.

Also, the contact structure 190b employed in some example embodiments may have a first extension portion 190a disposed in the trench and second extension portions 190b″, similarly to some aforementioned example embodiments. In some example embodiments, the second extension portions 190b″ may pass by both side surfaces of the source/drain pattern 150″ and the fence spacers 174 and may extend to an upper surface of the device isolation layer 110. In some example embodiments, a metal-semiconductor compound layer 180 may be disposed on both side surfaces of the source/drain pattern 150″ in which the second extension portion 190b″ is formed.

FIGS. 7A to 7D are cross-sectional diagrams a portion of processes (e.g., forming a fin structure and a dummy gate structure) of a method of manufacturing a semiconductor device according to an example embodiment.

First, referring to FIG. 7A, a semiconductor stack ST in which a first semiconductor layers 120 and a second semiconductor layers 140 are alternately stacked may be formed on a substrate 101.

The first semiconductor layers 120 may be removed in a subsequent process and may be used as a sacrificial layer, and the second semiconductor layers 120 may be used as a channel layer. The first semiconductor layers 120 and the second semiconductor layers 140 may include a semiconductor material including at least one of silicon (Si), silicon germanium (SiGe), and germanium (Ge), and may include different semiconductor materials. The first semiconductor layers 120 may be formed of a material having a high etch selectivity with respect to the second semiconductor layers 140. The second semiconductor layers 140 may include impurities, but example embodiments thereof are not limited thereto. In some example embodiments, the first semiconductor layers 120 may include silicon germanium (SiGe), and the second semiconductor layers 140 may include silicon (Si). The first semiconductor layers 120 and the second semiconductor layers 140 may be grown on the substrate 101 using an epitaxial growth process. Each of the first semiconductor layers 120 and the second semiconductor layers 140 may have a thickness ranging from approximately 2 nm to 100 nm.

Thereafter, referring to FIG. 7B, an active structure may be formed by removing a portion of the semiconductor stack ST and the substrate 101 using a first mask pattern M1 extending in the first direction (e.g., X-direction).

The active structure may include an active pattern 105 and a fin structure FS. The active pattern may include a structure protruding from an upper surface of the substrate 101 by removing a portion of the substrate 101, and the fin structure FS may include first semiconductor patterns 120 and second semiconductor patterns 140 alternately stacked on the active pattern 105. The active pattern 105 and the fin structure FS may be formed in the form of a line extending in one direction, for example, the first direction (e.g., X-direction). In the region from which a portion of the substrate 101 has been removed, an insulating material may be filled therein and may be etched back such that a portion of the active pattern 105 may protrude, thereby forming a device isolation layer 110. For example, an upper surface of the device isolation layer 110 may be etched back lower than an upper surface of the active pattern 105.

Thereafter, referring to FIG. 7C, dummy gate structures DG extending in the second direction (e.g., Y-direction) to intersect a portion of the active structure may be formed.

The dummy gate structures DG may be a sacrificial structure formed in the region in which the gate insulating layer 162 and the gate electrode 165 are disposed on the first to third channel layers 141, 142, and 143 illustrated in FIG. 2 through a subsequent process. The dummy gate structures DG may have a line shape intersecting the active structures and extending in the second direction (e.g., Y-direction), and may be spaced apart from each other in the first direction (e.g., X-direction). After forming the first and second sacrificial gate layers 172,175 sequentially stacked on the substrate 101 (e.g., the device isolation layer 110) on which the active structure is formed, dummy gate structures DG may be formed by patterning the stack using the second mask pattern M2.

The first and second sacrificial gate layers 172,175 may be an insulating layer and a conductive layer, respectively, but example embodiment thereof are not limited thereto, or the first and second sacrificial gate layers 172,175 may be integrated with each other. In some example embodiments, the first sacrificial gate layer 172 may include silicon oxide and the second sacrificial gate layer 175 may include polysilicon. The second mask pattern M2 may include silicon oxide and/or silicon nitride.

Thereafter, referring to FIG. 7D, gate spacers 164 on both side surfaces of the dummy gate structures DG and fence spacers 174 on both side surfaces of the active structure may be formed.

A spacer material layer may be conformally formed on the dummy gate structure DG and the active structure, and anisotropic etching may be applied, thereby forming gate spacers 164 on both side surfaces of the dummy gate structure DG, and fence spacers 174 may be formed on both side surfaces of the active structure, for example, the active pattern 105 and both side surfaces of the fin structure FS. Both side surfaces formed with gate spacers 164 may be opposing side surfaces disposed in the first direction (e.g., X-direction) of dummy gate structures DG, and both side surfaces on which fence spacers 174 are formed may be opposing side surfaces disposed in the second direction (e.g., Y-direction) of the active structure. Also, the gate spacers 164 and the fence spacers 174 may be formed of the same material. The spacer material layer, for example, the gate spacers 164 and the fence spacers 174, may be formed of a low-κ material and may include, for example, at least one of SiO, SiN, SiCN, SiOC, SiON, and SiOCN, but example embodiments are not limited thereto.

FIGS. 8A to 8F are cross-sectional diagrams of another portion of processes (e.g., forming a source/drain pattern) of a method of manufacturing a semiconductor device according to an example embodiment.

FIG. 8A illustrates the cross-sectional surface of the semiconductor structure in FIG. 7D taken along line I-I′, and the cross-sectional surface of the semiconductor structure in FIG. 7D taken along lines II1-II1′ and II2-II2′. In some example embodiments, sacrificial layers 120 may correspond to the first semiconductor pattern 120 illustrated in FIG. 7D, and channel layers 141, 142, and 143 may correspond to the second semiconductor pattern 140 illustrated in FIG. 7A.

Thereafter, referring to FIG. 8B, a recess RC may be formed by removing portions of the fin structure FS disposed on both sides of the dummy gate structures DG.

The exposed sacrificial layers 120 and the channel layers 141, 142, and 143 may be removed using the second mask pattern M2 and the gate spacers 164 as a mask. Through this process, lengths of channel layers 141, 142, and 143 in the first direction (e.g., X-direction) may be determined. The sacrificial layers 120 and the channel layers 141, 142, and 143 may be partially removed from a side surface below the dummy gate structures DG, such that both side surfaces in the first direction (e.g., X-direction) may be disposed below the dummy gate structures DG and the gate spacers 164. Also, after this process, the fence spacers 174 disposed on both side surfaces of the active structure may remain. In the process of removing the exposed portions of the sacrificial layers 120 and the channel layers 141, 142, and 143, a portion of the fence spacers 174 may also be removed, and accordingly, a height of the fence spacers 174 may be determined.

Thereafter, referring to FIG. 8C, the first epitaxial layer 150A to form the source/drain patterns 150 may be formed in the recess RC disposed on both sides of the dummy gate structures DG.

The first epitaxial layer 150A may include silicon germanium (SiGe). The first concentration of germanium (Ge) in the first epitaxial layer 150A may be 5 atomic % to 20 atomic %. The first epitaxial layer 150A may include P-type impurities. For example, P-type impurities may include at least one of B, Al, Ga, and In. The first epitaxial layer 150A may be grown continuously from an upper region of active pattern 105, which is a bottom surface of the recess region RC, and side surfaces of the channel layers 141, 142, and 143. The growth process of the first epitaxial layer 150A may include growing from the upper region of the active pattern 105 and the side surfaces of the plurality of channel layers 141, 142, and 143, merging portions grown from the side surfaces of adjacent channel layers 141, 142, and 143 with each other, and growing the first epitaxial layer 150A continuously along a sidewall of the recess RC. Such growth conditions may be obtained, for example, by adjusting growth pressure, growth temperature and/or gas flow rate.

Thereafter, referring to FIG. 8D, the second epitaxial layer 150B and the third epitaxial layer 150C may be grown on the first epitaxial layer 150A, thereby forming the source/drain pattern 150.

The second epitaxial layer 150B may be grown from the first epitaxial layer 150A using the SEG process. The second epitaxial layer 150B may include silicon germanium having a second Ge concentration greater than a first Ge concentration of the first epitaxial layer 150A. For example, the second concentration of the second epitaxial layer 150B may be 30 atomic % to 70 atomic %. The second epitaxial layer 150B may include P-type impurities. For example, P-type impurities may include at least one of B, Al, Ga, and In.

As described above, the second epitaxial layer 150B may control the width in the second direction by suppressing growth in the lateral direction. In some example embodiments, growth in this lateral direction may be prevented (or reduced) by adjusting the growth conditions of the second epitaxial layer 150B or performing an etching process during the growth process. In some example embodiments, by selecting a crystal growth plan (e.g., a crystal plane of an upper surface of the substrate) as a specific crystal plane, the second epitaxial layer 150B may be grown less in the lateral direction and may have a relatively narrow (or may have a narrow) width. Also, a third epitaxial layer 150C may be grown as a cap layer on the second epitaxial layer 150B. The third epitaxial layer 150C may include germanium (Ge).

Thereafter, referring to FIG. 8E, the interlayer insulating layer 115 may be formed, and the sacrificial layers 120 and the dummy gate structures DG may be removed, thereby forming upper gap regions UR and lower gap regions LR.

The interlayer insulating layer 115 may be formed by forming an insulating film covering the dummy gate structures DG and the source/drain patterns 150 and performing a planarization process. The sacrificial layers 120 and the dummy gate structure DG may be selectively removed for the gate spacers 164, the interlayer insulating layer 115, and the channel layers 141, 142, and 143. First, the upper gap regions UR may be formed by removing the dummy gate structures DG along with the second mask pattern M2, and the lower gap regions LR may be formed by removing the sacrificial layers 120 exposed through the upper gap regions UR. For example, when the sacrificial layers 120 include silicon germanium (SiGe) and the channel structure 140 includes silicon (Si), the sacrificial layers 120 may be selectively removed by performing a wet etching process using peracetic acid as an etchant. During the removal process, the source/drain patterns 150 may be protected by the interlayer insulating layer 115.

Thereafter, referring to FIG. 8F, gate structures 160 may be formed in the upper gap regions UR and the lower gap regions LR.

First, the gate insulating layer 162 may be formed to conformally cover internal surfaces of the upper gap regions UR and the lower gap regions LR. The gate electrodes 165 may be formed to completely fill (or to fill) the upper gap regions UR and the lower gap regions LR, and may be removed from the upper gap regions UR to a predetermined (or desired) depth. A gate capping layer 166 may be formed in the region in which the gate electrodes 165 are removed from the upper gap regions UR. Through the processes, the gate structures 160 including the gate insulating layer 162, the gate electrode 165, the gate spacers 164, and the gate capping layer 166 may be formed.

FIGS. 9A to 9D are cross-sectional diagrams illustrating the other portion of processes (e.g., forming a contact structure) of a method of manufacturing a semiconductor device according to an example embodiment.

Referring to FIG. 9A, a contact hole CH may be formed in an interlayer insulating layer 115, and a blocking insulating layer 178 may be formed conformally.

A contact hole CH for a contact structure 190 may be formed by partially removing the interlayer insulating layer 115 between the gate structures 160. In some example embodiments, a width of the contact hole CH in the first direction (e.g., X-direction) may be defined by spacing between the gate structures 160. The width of the contact hole CH in the second direction (e.g., Y-direction) may be slightly larger (or may be larger) than a width of the source/drain pattern 150. Accordingly, side surfaces of the source/drain pattern 150 may be opened through the contact hole CH. In some example embodiments, the width of the contact hole CH in the first direction (e.g., X-direction) may be relatively smaller (or may be smaller) than a spacing between the gate structures 160. In some example embodiments, the interlayer insulating layer 115 may remain on opposing sidewalls of the gate structures 160. The width of the contact hole CH in the second direction (e.g., Y-direction) may be the same as or slightly smaller (or smaller) than the width of the source/drain pattern 150, and after the blocking insulating layer 178 is removed, a process of expanding the contact hole CH in the second direction (e.g., X-direction) may be added such that the side surfaces of the source/drain pattern 150 may be opened through the contact hole CH.

Thereafter, the blocking insulating layer 178 may be conformally formed on an upper surface and a sidewall of the gate structures 160 and a surface of the interlayer insulating layer 115. The blocking insulating layer 178 may prevent (or reduce) a region below the gate structure 160 from being damaged during a process of forming a trench DT in the source/drain pattern 150 (e.g., see the process in FIG. 9B). For example, the blocking insulating layer 178 may be silicon nitride.

Thereafter, referring to FIG. 9B, the source/drain patterns 150 may be opened by partially etching the blocking insulating layer 178, and a trench DT may be formed in the source/drain patterns 150.

Upper surfaces of the gate structure 160 and the source/drain pattern 150 may be opened by etching the blocking insulating layer 178 using an anisotropic etching process such as reactive ion etching. In some example embodiments, the third epitaxial layer 150C may be open. Thereafter, a trench DT may be formed in the source/drain pattern 150 by etching the source/drain pattern 150 using the patterned blocking insulating layer 178. A depth of the trench DT may be formed to overlap at least a portion of the first channel layer 141, which is a lowermost layer. In the process of forming the trench DT, the second epitaxial layer 150B may be removed along with the third epitaxial layer 150C, thereby forming a trench DT. The trench DT may have a structure surrounded by the second epitaxial layer 150B in a plane view.

Thereafter, referring to FIG. 9C, the blocking insulating layer 178 may be removed, and a metal-semiconductor compound layer 180 may be formed on a surface of the source/drain pattern 150.

In some example embodiments, the blocking insulating layer 178 may be selectively removed (or may be removed) from a sidewall of the contact hole CH. By removing the blocking insulating layer 178, both side surfaces in the second direction (e.g., Y-direction) of the source/drain patterns 150 may be sufficiently exposed (or may be exposed). Thereafter, a metal-semiconductor compound layer 180 may be formed on a surface of the source/drain pattern 150. The metal-semiconductor compound layer 180 may be formed by depositing a metal layer (e.g., Ti) mainly on (or on) the exposed third epitaxial layer 150C and annealing the layer. The metal-semiconductor compound layer 180 may be formed on an upper surface of the source/drain pattern 150, and also on both side surfaces in the second direction (e.g., Y-direction). For example, the metal-semiconductor compound layer 180 may include TiGe, or TiSiGe.

In this process, most of the third epitaxial layer 150C may be metalized and may not remain in a final structure. Also, a portion of the adjacent second epitaxial layer 150B may also be metallized. In some example embodiments, when the blocking insulating layer barely remains (or remains) on the surface of the source/drain pattern 150 after the trench DT is formed, a process of forming the metal-semiconductor compound layer 180 may be performed without an additional removal process (e.g., see FIG. 5B).

Thereafter, referring to FIG. 9D, a contact structure 190 connected to a surface of the source/drain pattern 150 may be formed within the contact hole CH and the trench DT.

The contact structure 190 may be formed to have a first extension portion 190a in the trench DT and a pair of second extension portions 190b extending to both side surfaces of the source/drain pattern 150. Since the trench has a sufficient depth (or a depth), the first extension portion 190a may be formed such that at least a portion thereof may overlap the first channel layer 141, which is the lowermost layer, in the horizontal direction. The second extension portions 190b may extend along both side surfaces of the source/drain patterns 150 in the second direction (e.g., Y-direction), for example, along the surface of the second epitaxial layer 150B. Also, the metal-semiconductor compound layer 180 may be disposed on an upper surface of the contact structure 190 and an internal surface of the trench DT, and also on the side surfaces of the source/drain patterns 150 in contact with the second extension portions 190b.

By increasing the contact area with the source/drain patterns 150 through the first extension portion 190a and also the second extension portions 190b as described above, the contact structure 190 may greatly improve (or may improve) the contact resistance.

According to some aforementioned example embodiments, by forming a trench in the source/drain pattern and forming a contact structure having the first extension portion extending to the trench and the second extension portions extending to both side surfaces of the source/drain pattern, contact resistance of the source/drain pattern and the contact structure may be reduced.

While some example embodiments have been illustrated and described above, it will be configured as apparent to those skilled in the art that modifications and variations may be made without departing from the scope in the example embodiments as defined by the appended claims.

What is claimed is:

1. A semiconductor device, comprising:
a substrate;
an active pattern extending on the substrate in a first direction;
a device isolation layer on the substrate and defining the active pattern;
a plurality of channel layers arranged on the active pattern and spaced apart from each other in a direction perpendicular to an upper surface of the substrate;
a gate structure crossing the active pattern, and surrounding the plurality of channel layers, and the gate structure extending in a second direction intersecting the first direction;
source/drain patterns including a first epitaxial layer on a portion of the active pattern at both sides of the gate structure along side surfaces of the plurality of channel layers and a second epitaxial layer on the first epitaxial layer and having a trench;
contact structures on the source/drain patterns, respectively, and including a first extension portion filling the trench, and a pair of second extension portions extending along both side surfaces of each of the source/drain patterns in the second direction, respectively; and
a metal-semiconductor compound layer between the source/drain patterns and the contact structures.

2. The semiconductor device of claim 1, wherein the first extension portion of the contact structures has at least a portion overlapping a lowest channel layer of the plurality of channel layers in a direction parallel to the upper surface of the substrate.

3. The semiconductor device of claim 1, wherein a portion of the contact structures adjacent to the gate structure has a width in the second direction greater than a width in the second direction of the first extension portion.

4. The semiconductor device of claim 1, wherein the second extension portions of the contact structures extend along a surface of the second epitaxial layer of the source/drain patterns.

5. The semiconductor device of claim 1, wherein the second extension portions of the contact structures extend up to the device isolation layer.

6. The semiconductor device of claim 1, further comprising:
fence spacers on both side surfaces of the active pattern in the second direction.

7. The semiconductor device of claim 6, wherein the second extension portions of the contact structures extend to the fence spacers.

8. The semiconductor device of claim 6, wherein a difference between a maximum width of the source/drain patterns in the second direction and a width of a portion of the source/drain patterns between the fence spacers is 20 nm or less.

9. The semiconductor device of claim 6, wherein a portion of the source/drain patterns, arranged above the fence spacers, does not have a convex portion on both side surfaces in the second direction.

10. The semiconductor device of claim 1, wherein the source/drain patterns is P-type source/drain patterns.

11. The semiconductor device of claim 1, wherein each of the first epitaxial layer and the second epitaxial layer includes silicon germanium (SiGe), and a first concentration of germanium (Ge) in the first epitaxial layer is lower than a second concentration of germanium (Ge) in the second epitaxial layer.

12. The semiconductor device of claim 11,
wherein a first concentration of the first epitaxial layer is 5 atomic % to 20 atomic %, and
wherein a second concentration of the second epitaxial layer is 30 atomic % to 70 atomic %.

13. The semiconductor device of claim 1, further comprising:
internal spacers on both side surfaces of the gate structure in the first direction below a lower surface of each of the plurality of channel layers.

14. A semiconductor device, comprising:
a substrate;
an active pattern extending on the substrate in a first direction;
a plurality of channel layers arranged on the active pattern and spaced apart from each other in a direction perpendicular to an upper surface of the substrate;
a gate structure crossing the active pattern, and surrounding the plurality of channel layers, and the gate structure extending in a second direction intersecting the first direction;
fence spacers on both side surfaces of the active pattern in the second direction at both sides of the gate structure;
source/drain patterns including epitaxial layers connected to side surfaces of the plurality of channel layers, respectively, on a portion of the active pattern on both sides of the gate structure, and the source/drain patterns having a trench in the epitaxial layer; and
contact structures on the source/drain patterns, respectively, each contact structure including a first extension portion filling the trench, and a pair of second extension portions extending to the fence spacers, respectively, along both side surfaces of each of the source/drain patterns in the second direction.

15. The semiconductor device of claim 14, wherein a maximum width of the source/drain patterns in the second direction is less than 120% of a width of a portion of the source/drain patterns between the fence spacers.

16. The semiconductor device of claim 14, further comprising:
a metal-semiconductor compound layer between the source/drain patterns and the contact structures.

17. The semiconductor device of claim 14, wherein an epitaxial layer of the source/drain patterns includes:
a first epitaxial layer on a portion of the active pattern along side surfaces of the plurality of channel layers, and
a second epitaxial layer on the first epitaxial layer and defining the trench.

18. The semiconductor device of claim 17, wherein the second extension portions of the contact structures extend along side surfaces of the second epitaxial layer.

19. A semiconductor device, comprising:
a substrate;
an active pattern extending on the substrate in a first direction;
a plurality of channel layers arranged on the active pattern and spaced apart from each other in a direction perpendicular to an upper surface of the substrate;
a gate structure crossing the active pattern, surrounding the plurality of channel layers, and extending in a second direction intersecting the first direction;
source/drain patterns including a first epitaxial layer along side surfaces of the plurality of channel layers on a portion of the active pattern, and a second epitaxial layer on the first epitaxial layer and having a trench deeper than a level of an upper surface of a lowermost channel layer among the plurality of channel layers;
contact structures on the source/drain patterns, respectively, each contact structure including a first extension portion filling the trench and a pair of second extension portions extending along both side surfaces of each of the source/drain patterns in the second direction; and
a metal-semiconductor compound layer between the source/drain patterns and the contact structures.

20. The semiconductor device of claim 19, wherein each of epitaxial layers of the source/drain patterns includes an epitaxial layer doped with P-type impurities.
